(19) United States
(12) Patent Application Publication
(10) Pub. No.: US 2024/0105467 A1
(43) Pub. Date: Mar. 28, 2024

(54) SEMICONDUCTOR DEVICE AND METHOD FOR MAKING THE SAME

(71) Applicant: STATS ChipPAC Pte. Ltd., Singapore (SG)

(72) Inventors: MyungHo JUNG, gyeonggi-do (KR); SangHyun SON, Seoul (KR); YoungUk NOH, Seoul (KR)

(21) Appl. No.: 18/460,621

(22) Filed: Sep. 4, 2023

(30) Foreign Application Priority Data
Sep. 19, 2022 (CN) 202211138172.6

(51) Int. Cl. H01L 21/48; H01L 23/498

(52) U.S. Cl. CPC H01L 21/4853; H01L 23/49811; H01L 23/3121

(57) ABSTRACT

A semiconductor device and a method for forming the same are provided. The method includes: providing a package including: a substrate including a first substrate surface and a second substrate surface opposite to the first substrate surface; a first conductive bump formed on the first substrate surface; and a first encapsulant disposed on the first substrate surface and encapsulating the first conductive bump; forming a groove in the first encapsulant to expose at least a portion of the first conductive bump; and forming a second conductive bump on the exposed portion of the first conductive bump using a laser soldering apparatus.

### TECHNICAL FIELD

The present application generally relates to semiconductor technology, and more particularly, to a semiconductor device and a method for making the same.

### BACKGROUND OF THE INVENTION

System-in-Package (SiP) is a functional electronic system or sub-system that includes in a single package two or more heterogeneous semiconductor dice, such as a logic chip, a memory, integrated passive devices (IPDs), RF filters, sensors, heat sinks, or antennas. Recently, Double Side Molding (DSM) technology is used to further shrink the overall size of a SiP package. However, semiconductor devices formed using the conventional DSM technology may have low reliability.

Therefore, a need exists for semiconductor devices with improved reliability.

### SUMMARY OF THE INVENTION

An objective of the present application is to provide a method for making a semiconductor device with high reliability.

According to an aspect of embodiments of the present application, a method for making a semiconductor device is provided. The method may include: providing a package including: a substrate including a first substrate surface and a second substrate surface opposite to the first substrate surface; a first conductive bump formed on the first substrate surface; and a first encapsulant disposed on the first substrate surface and encapsulating the first conductive bump; forming a groove in the first encapsulant to expose at least a portion of the first conductive bump; and forming a second conductive bump on the exposed portion of the first conductive bump using a laser soldering apparatus.

According to another aspect of embodiments of the present application, a semiconductor device is provided. The semiconductor device can be made according to the method described above, and may include: a substrate including a first substrate surface and a second substrate surface opposite to the first substrate surface; a first conductive bump formed on the first substrate surface; a first encapsulant disposed on the first substrate surface and encapsulating the first conductive bump; a groove disposed in the first encapsulant and exposing at least a portion of the first conductive bump; and a second conductive bump disposed on the exposed portion of the first conductive bump, which is formed using a laser soldering apparatus.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view of a semiconductor device formed using a Double Side Molding (DSM) technology.

FIGS. 2 to 9 are cross-sectional views illustrating various steps of a method for making a semiconductor device according to an embodiment of the present application.

FIG. 10A and FIG. 10B illustrate a laser soldering process and apparatus according to an embodiment of the present application.

FIG. 11 illustrates another laser soldering apparatus according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

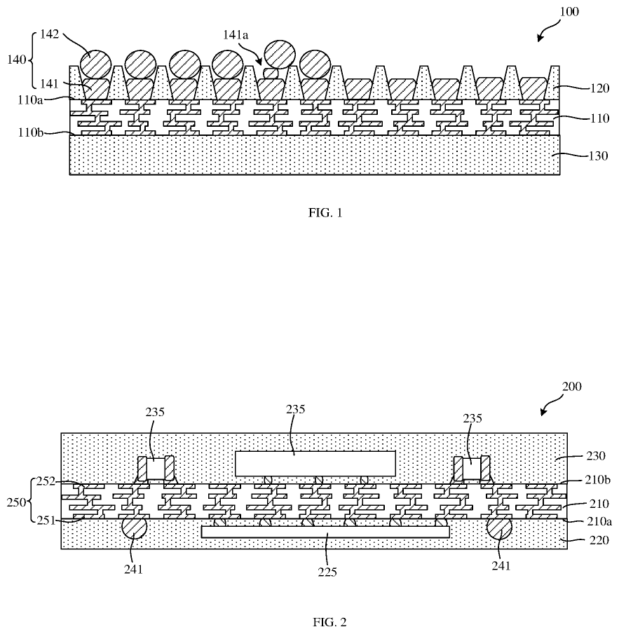

FIG. 1 illustrates a cross-sectional view of a semiconductor device 100 formed using a Double Side Molding (DSM) technology.

As shown in FIG. 1, the semiconductor device 100 includes a substrate 110 with a first substrate surface 110a and a second substrate surface 110b which is opposite to the first substrate surface 110a. One or more first electronic components (not shown) may be mounted on the first substrate surface 110a, and one or more second electronic components (not shown) may be mounted on the second substrate surface 110b. A first encapsulant 120 is disposed on the first substrate surface 110a and covers the first electronic components to protect against thermal shock, physical attach, fluid penetration, etc. Similarly, a second encapsulant 130 is disposed on the second substrate surface 110b and covers the second electronic components for similar protection purpose.

A plurality of external interconnect structures 140 are formed on the first substrate surface 110a and electrically connected to the first electronic components and/or further to the second electronic components via interconnection structures within the substrate 110. The external interconnect structures 140 are used to interface or attach the semiconductor device 100 to an external device, such as to an external substrate. Accordingly, the external interconnect structures 140 may protrude from the first substrate surface 110a further than a top surface of the first encapsulant 120, to ensure contact with the external substrate. In the example shown in FIG. 1, the external interconnect structures 140 are formed using a two-step solder ball mounting (SBM) process. Specifically, first solder balls 141 are first formed on the first substrate surface 110a and enclosed by the first encapsulant 120. Then, a laser ablation process may be employed to form grooves in the first encapsulant 120 to expose the respective first solder balls 141. Next, a second solder ball 142 may be formed on each first solder ball 141, so as to obtain a desired height of the external interconnect structures 140.

However, the laser ablation process may damage the first solder ball 141 or result in an abnormal shape of the first solder ball 141, such as the abnormal first solder ball 141a shown in FIG. 1. Consequently, when forming the second solder ball 142, solder bridges may be formed over the first encapsulant 120 between two adjacent second solder balls 142, resulting in leakage of the semiconductor device 100. In some cases, some of the first solder balls 141 may be volatilized during the laser ablation process, and thus the external interconnect structures 140 cannot be successfully formed in the two-step SBM process.

To address at least one of the above problems, a method for making a semiconductor device is provided in an aspect of the present application. In the method, a laser soldering technique is used to stack a second solder ball on each first solder ball. The laser soldering technique can accurately control a height of the second solder ball to be formed, and further a height of the external interconnect, i.e., a total height of the first solder ball and the second solder ball. Thus, a fine-pitch ball array can be formed on the semiconductor device, and an overall size of the package can be reduced. Further, the laser soldering technique can form the second solder ball independent of the shape of the first solder ball and can easily re-form a solder ball that is missed in the laser ablation process. Thus, the solder bridges formed using the two-step SBM process can be avoided, resulting in an improved reliability of a semiconductor device with such solder balls.

Referring to FIGS. 2 to 9, various steps of a method for making a semiconductor device are illustrated according to an embodiment of the present application. In the following, the method will be described with reference to FIGS. 2 to 9 in more details.

Referring to FIG. 2, a package 200 is provided. The package 200 may include a substrate 210, a first encapsulant 220, a first electronic component 225, a second encapsulant 230, second electronic component(s) 235 and first conductive bump(s) 241.

In particular, the substrate 210 has a first substrate surface 210a and a second substrate surface 210b opposite to the first substrate surface 210a. In some embodiments, the substrate 210 may include a redistribution structure (RDS) having one or more dielectric layers and one or more conductive layers between and through the dielectric layers. The conductive layers may define pads, traces and plugs through which electrical signals or voltages can be distributed horizontally and vertically across the RDS. As shown in the example of FIG. 2, the RDS 250 may include a plurality of first conductive patterns 251 formed on the first substrate surface 210a and a plurality of second conductive patterns 252 formed on the second substrate surface 210b. In addition, the RDS 250 may further include one or more conductive vias electrically connecting at least one of the first conductive patterns 251 formed on the first substrate surface 210a with at least one of the second conductive patterns 252 formed on the second substrate surface 210b. The RDS 250 may include one or more of Al, Cu, Sn, Ni, Au, Ag, or any other suitable electrically conductive material. It could be appreciated that, the first conductive patterns 251, the second conductive patterns 252 and the conductive vias may be implemented in various structures and types, but aspects of the present application are not limited to the above example.

The first electronic component 225 may be mounted on the first substrate surface 210a and electrically connected to one or more of the first conductive patterns 251. The first electronic component may include semiconductor dice and discrete devices. In the example of FIG. 2, the first electronic component 225 is shown as a semiconductor die. The semiconductor die 225 is formed in a flip-chip type and may be mounted such that conductive bumps of the semiconductor die 225 can be welded to some of the first conductive patterns 251. In some other embodiments, the semiconductor die 225 may include bond pads and may be connected to the first conductive patterns 251 by wire bonding. The present application does not limit the connection between the semiconductor die 225 and the first conductive patterns 251 to that disclosed herein. The first electronic component 225 is attached to some of the second conductive patterns 252, while the remaining of the first conductive patterns 251 may be exposed. These exposed or uncovered first conductive patterns 251 can ensure that electrical connection to the first electronic component 225 is available to the exterior environment.

The second electronic component 235 may be mounted on the second substrate surface 210b and electrically connected to one or more of the second conductive patterns 252. In the example of FIG. 2, the second electronic component 235 includes a semiconductor die formed in a flip-chip type and two discrete devices. In other embodiments, the second electronic component 235 may include more semiconductor dice or discrete devices, but aspects of the present application are not limited thereto.

As aforementioned, the first electronic component 225 or the second electronic component 235 may include a semiconductor die or a discrete device. For example, the first electronic component 225 and the second electronic component 235 may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc. the first electronic component 225 and the second electronic component 235 may also include one or more passive electrical components such as resistors, capacitors, inductors, etc.

The first conductive bumps 241 may be disposed on the first substrate surface 210a and electrically connected to some of the first conductive patterns 251. The conductive bump 241 may include conductive pillars, copper pillars, conductive balls or copper balls, but aspects of the present disclosure are not limited thereto. Although the conductive bumps 241 are presented as solder balls in the example shown in FIG. 2, there can be other examples where one or more of the solder balls may be other conductive balls, or conductive pillars, or conductive posts. For example, the first conductive bumps 241 may include one or more of Sn, Ni, Al, Cu, Au, Ag, or other suitable electrically conductive material.

The first encapsulant 220 may be disposed on the first substrate surface 210a and cover the first electronic component 225 and the first conductive bumps 241. The second encapsulant 230 may be disposed on the second substrate surface 210b of the substrate 210 and cover the second electronic component 235. The first encapsulant 220 and the second encapsulant 230 may protect the first electronic component 225 and the second electronic component 235 from external environment respectively. The first encapsulant 220 and the second encapsulant 230 may be made of a general molding compound resin, for example, an epoxy-based resin, but the scope of this application is not limited thereto.

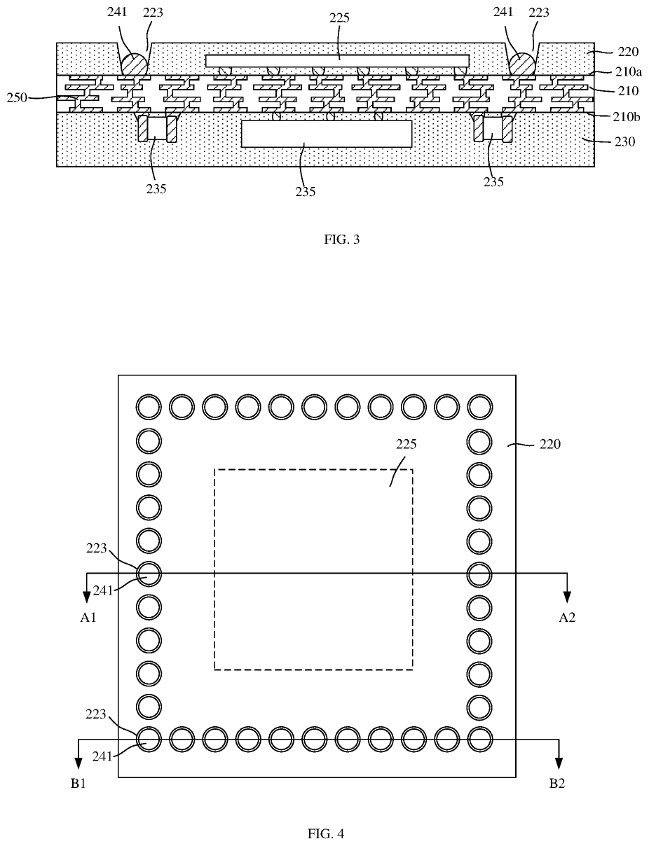

Referring to FIG. 3, the package 200 is flipped and a plurality of grooves 223 are formed in the first encapsulant 220. Each groove 223 may expose at least a portion of a respective conductive bump 241. In some embodiments, a laser ablation process may be employed to form the groove 223 in the first encapsulant 220. In addition, the groove 223 may be formed by an etching process, or any other process known in the art so long as the encapsulant material above the conductive bump 241 can be removed. In some embodiments, after forming the groove 223, a cleaning process for removing residuals may further be performed.

In the example shown in FIG. 3, the groove 223 may expose a smaller portion of the outer surface of the first conductive bump 241. In another example, the groove 223 may expose most of the outer surface of the first conductive bump 241. In general, a width of the groove 223 may be larger than a diameter of the conductive bump 241, so as to facilitate subsequent ball formation steps and realize better electrical performance.

FIG. 4 is a top view illustrating the package shown in FIG. 3, while FIG. 3 is a cross-sectional view of the package along a section line A1-A2 shown in FIG. 4. As can be seen from FIG. 4, the first conductive bumps 241 and the grooves 223 are formed around the first electronic component 225. In order to show the first conductive bumps 241 and the grooves 223 more clearly, a cross-sectional view of the package along another section line B1-B2 shown in FIG. 4 is further provided in FIG. 5.

As illustrated in FIG. 5, when the grooves 223 in the first encapsulant 220 is formed, some first conductive bumps 241 may be damaged by the laser ablation process. For example, a conductive bump 241a may be deformed in the laser ablation process, and another conductive bump at the location 241b may be missing in the laser ablation process, which may reduce the reliability of the semiconductor device to be formed.

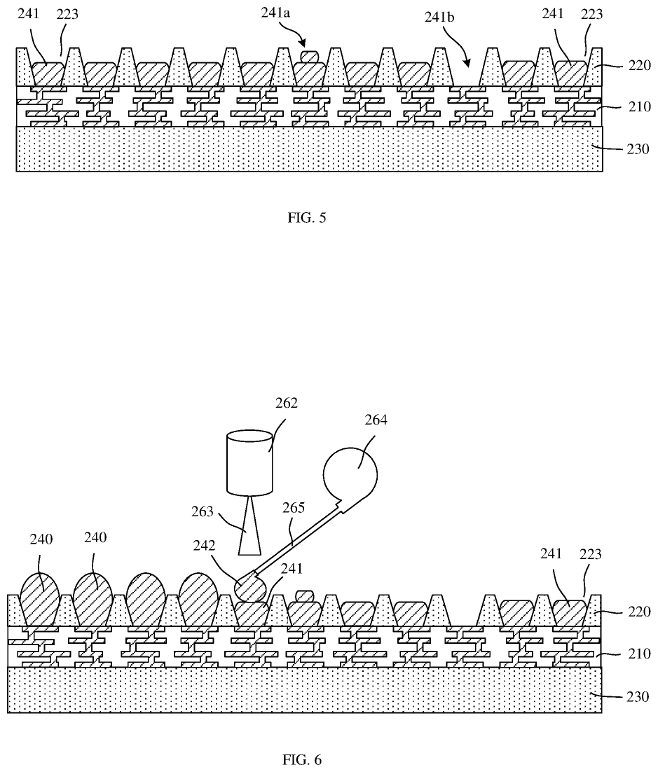

To address the potential damage issue to the conductive bumps 241, Referring to FIG. 6, second conductive bumps 242 may be formed on the exposed portions of the respective first conductive bumps 241 using a laser soldering apparatus. After the laser soldering process, the second conductive bumps 242 can protrude from the grooves 223, i.e., higher than the grooves 223.

As shown in FIG. 6, the laser soldering apparatus may include a light source 262 and a solder supplying component 264. The light source 262 is used to irradiate a laser beam 263 with a predetermined intensity. In some embodiments, the laser beam 263 may include infrared light, or other lights suitable for heating and reflowing the materials of the first conductive bump 241 and the second conductive bump 242. For example, the laser beam 263 may have a wavelength of 808 nm, 940 nm, 980 nm, etc. However, the present application is not limited to the above examples. Furthermore, the solder supplying component 264 is used to supply a solder wire 265 into the groove 223. For example, the solder supplying component 264 can feed a predetermined amount of the solder wire 265 to a target position in the grooves 223. In some embodiments, the laser soldering apparatus may further include a control device (e.g., a micro controller unit) for controlling operations of the light source 262 and the solder supplying component 264. For example, the control device can control an intensity and/or duration of the laser beam 263 irradiated from the light source 262, and/or a supply timing and a supply amount of the solder material supplied by the solder supplying component 264.

In an exemplary process for forming the second conductive bumps 242, at first the light source 262 may irradiate the laser beam 263 to pre-heat the first conductive bumps 241 to a desired temperature; and then, a predetermined mount of solder wire 265 can be supplied from the solder supplying component 264 to the respective first conductive bumps 241. Afterwards, the predetermined mount of solder can be melted by the laser beam 263 irradiated from the light source 262 to form the respective second conductive bumps 242. Lastly, the first conductive bumps 241 and the second conductive bumps 242 can be further post-heated by the laser beam 263, such that each pair of the first conductive bump 241 and the second conductive bump 242 can be melted together to form an interconnect structure 240 as shown in FIG. 6.

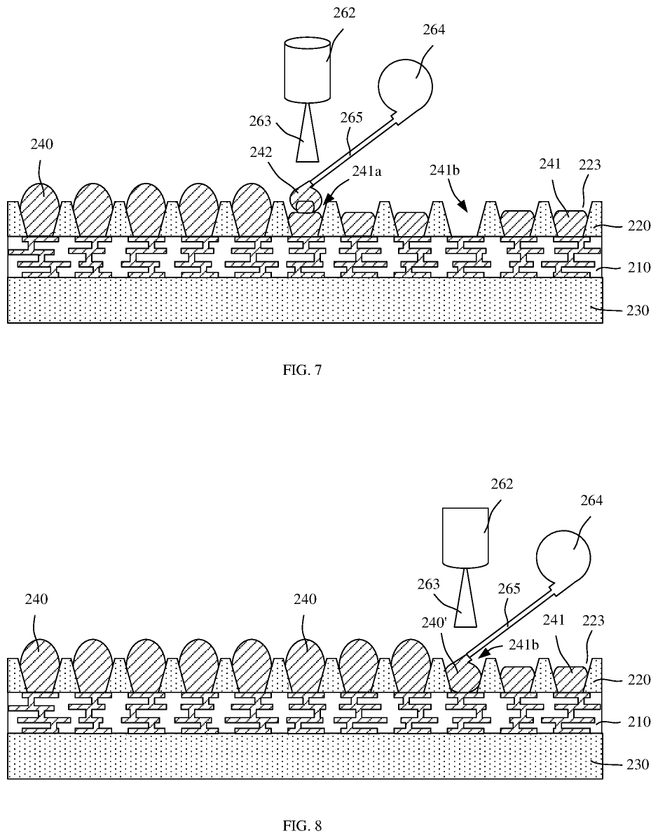

Referring to FIG. 7, as the laser soldering apparatus can easily and accurately control the position and the amount of solder material deposited on the first conductive bumps 241, the second conductive bumps 242 can also be formed on the respective conductive bumps 241a, regardless of whether any of the conductive bumps 241a is deformed during previous steps and what shape the deformed conductive bump 241a is.

Further referring to FIG. 8, the laser soldering apparatus can directly form an interconnect structure 240′ similar as other interconnect structures 240 at a location 241b where the first conductive bump is missing or partially missing after the laser ablation process to the encapsulant. Thus, there is no need to reform the missing conductive bumps, avoiding thermal stress caused by an additional reflow process for reforming the missing bumps.

It can be appreciated that during the step shown in FIGS. 7 and 8 to supply the solder material of the second conductive bumps, the amount of the soldering material supplied can be controlled by the laser soldering apparatus. For example, if the first conductive bump is missing or partially missing, more solder material can be supplied. In some embodiments, a detection component such as a microscope can be used to detect the condition of the first conductive bumps formed in the respective grooves, and optionally, an image recognition algorithm can be implemented by the solder supplying apparatus or an external controller to automatically detect and recognize the condition of the first conductive bumps.

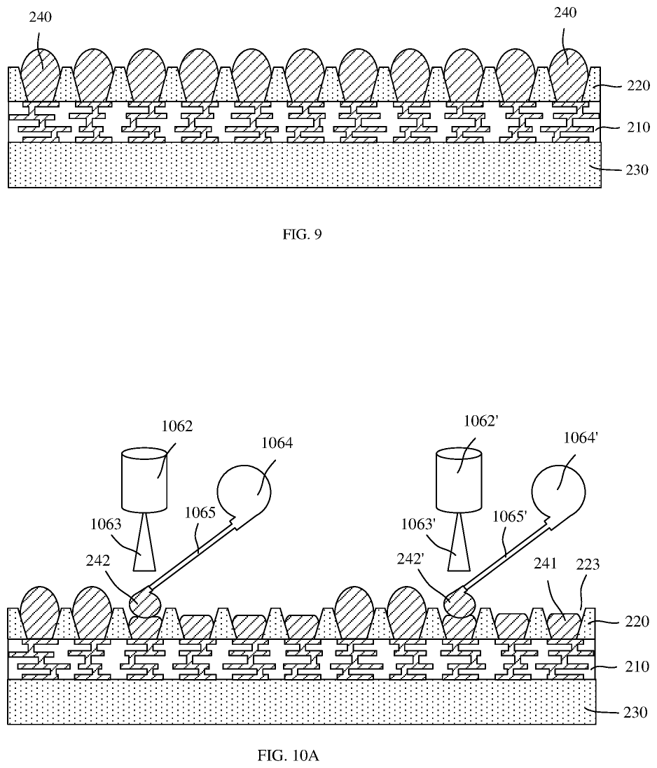

At last, as shown in FIG. 9, all the interconnect structures 240 may be formed to have a uniform height and configuration, and the reliability of the semiconductor device can be improved.

It could be understood that the configuration of the laser soldering apparatus shown in the FIGS. 6 to 8 and the laser soldering process described above are examples only and are not restrictive of the present application. Any other laser soldering apparatuses or laser soldering processes suitable for forming the second conductive bump can be used in the present application.

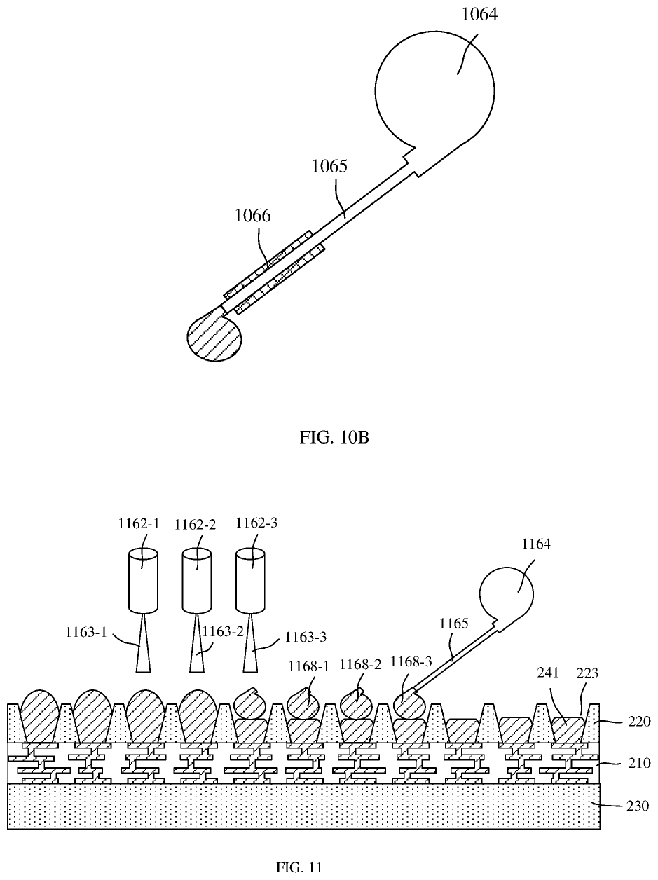

FIG. 10A and FIG. 10B illustrate another exemplary laser soldering process and apparatus according to another embodiment of the present application. The laser soldering apparatus shown in FIG. 10B can also be used to form a second conductive bump 242 on the exposed portion of each first conductive bump 241 as shown in FIG. 5, while FIG. 10A shows the laser soldering process implemented by the laser soldering apparatuses shown in FIG. 10B.

Referring to FIG. 10A, the laser soldering apparatus include two branches. One of the branches includes a first light source 1062 for irradiating a first laser beam 1063 and a first solder supplying component 1064 for supplying a first solder wire 1065, and the other of the branches includes a second light source 1062′ for irradiating a second laser beam 1063′ and a second solder supplying component 1064′ for supplying a second solder wire 1065′. The two branches of the laser soldering apparatus can operate simultaneously above the substrate to form two second conductive bumps 242 and 242′ on two first conductive bumps respectively, such that the productivity of the laser soldering apparatus can be increased. It can be appreciated that more branches can be included in the laser soldering apparatus. In some embodiments, the laser soldering apparatus may have a soldering array with multiples rows and columns of solder supplying components, each of which is paired with a laser source.

FIG. 10B is an enlarged view of the solder supplying component 1064 (or 1064′) of FIG. 10A according to an embodiment of the present application. As shown in FIG. 10B, the laser soldering apparatus may further include a pre-heater 1066 (for example, an electric heater) attached to the solder supplying component 1064. For example, the pre-heater 1066 may be wrapped around a supply channel and close to an outlet of the supply channel. In an exemplary process for forming the second conductive bumps using the solder supplying component 1064 shown in FIG. 10B, the pre-heater 1066 can be used to melt a portion of the solder wire 1065 supplied by the solder supplying component 1064 in advance, i.e., before it flows out of the supply channel. The solder supplying component 1064 can supply a predetermined mount of the melted solder material onto the exposed portion of each first conductive bump to form the second conductive bump 242 thereon. Thus, the light source 1062 is no longer used to melt the solder wire 1065, and the productivity of the laser soldering apparatus can be increased.

FIG. 11 illustrates another exemplary laser soldering process and apparatus according to another embodiment of the present application. The laser soldering apparatus can also be used to form a second conductive bump 242 on the exposed portion of the first conductive bump 241 as shown in FIG. 5.

Referring to FIG. 11, the laser soldering apparatus may include three light sources 1162-1, 1162-2 and 1162-3, and a solder supplying component 1164 for supplying a solder wire 1165. The three light sources 1162-1, 1162-2 and 1162-3 can respectively irradiate three laser beams 1163-1, 1163-2 and 1163-3 having a same wavelength or different wavelengths. In addition, the laser soldering apparatus also includes a wire cutting component (not shown) for cutting the solder wire 1165 into a plurality of wire segments.

In an exemplary process for forming the second conductive bump using the laser soldering apparatus shown in FIG. 11, the wire cutting component can be used to cut three wire segments 1168-1, 1168-2 and 1168-3 from the solder wire 1165, and then the three wire segments 1168-1, 1168-2 and 1168-3 are sequentially supplied onto three first conductive bumps by the solder supplying component 1164. At last, the three laser beams 1163-1, 1163-2 and 1163-3 can be irradiated by the respective three light sources 1162-1, 1162-2 and 1162-3 to melt the three wire segments 1168-1, 1168-2 and 1168-3 and form three second conductive bumps, either simultaneously or sequentially. Thus, the productivity of the laser soldering apparatus can be increased.

According to another aspect of the present application, a semiconductor device made by the methods described above is provided. The details of the semiconductor device may refer to the methods described above, and is not elaborated herein.

While the processes for making the semiconductor device are illustrated in conjunction with corresponding figures, it will be understood by those skilled in the art that modifications and adaptations to the process may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing a package comprising:
a substrate comprising a first substrate surface and a second substrate surface opposite to the first substrate surface;
a first conductive bump formed on the first substrate surface; and
a first encapsulant disposed on the first substrate surface and encapsulating the first conductive bump;
forming a groove in the first encapsulant to expose at least a portion of the first conductive bump; and
forming a second conductive bump on the exposed portion of the first conductive bump using a laser soldering apparatus.

2. The method of claim 1, wherein the second conductive bump protrudes outside the groove.

3. The method of claim 1, wherein the package further comprising:
a first electronic component mounted on the first substrate surface and encapsulated by the first encapsulant;
a second electronic component mounted on the second substrate surface; and
a second encapsulant disposed on the second substrate surface and encapsulating the second electronic component.

4. The method of claim 1, wherein the groove exposes a top surface and a portion of a lateral surface of the first conductive bump.

5. The method of claim 1, wherein forming the groove in the first encapsulant comprises:
forming the groove in the first encapsulant using a laser ablation process.

6. The method of claim 1, wherein the laser soldering apparatus comprises:
a light source configured for irradiating a laser beam; and
a solder supplying component configured for supplying a solder wire.

7. The method of claim 6, wherein forming the second conductive bump on the exposed portion of the first conductive bump comprises:
supplying, by the solder supplying component, a predetermined mount of solder onto the exposed portion of the first conductive bump; and
melting, by the light source, the predetermined mount of solder to form the second conductive bump.

8. The method of claim 7, further comprising:
pre-heating, by the light source, the first conductive bump to a predetermined temperature.

9. The method of claim 7, further comprising:
post-heating, by the light source, the first conductive bump and the second conductive bump to integrate them together.

10. The method of claim 6, wherein the laser soldering apparatus further comprises a pre-heater attached to the solder supplying component, and forming the second conductive bump on the exposed portion of the first conductive bump comprises:
melting, by the pre-heater, a portion of the solder wire supplied by the solder supplying component; and
supplying, by the solder supplying component, a predetermined mount of melted solder onto the exposed portion of the first conductive bump to form the second conductive bump.

11. The method of claim 10, further comprising:
pre-heating, by the light source, the first conductive bump to a predetermined temperature.

12. The method of claim 10, further comprising:
post-heating, by the light source, the first conductive bump and the second conductive bump to integrate them together.

13. The method of claim 6, wherein the laser soldering apparatus further comprises a wire cutting component, and forming the second conductive bump on the exposed portion of the first conductive bump comprises:
cutting, by the wire cutting component, a portion of the solder wire supplied by the solder supplying component;
supplying, by the solder supplying component, the portion of the solder wire onto the exposed portion of the first conductive bump; and
melting, by the light source, the portion of the solder wire to form the second conductive bump.

14. The method of claim 13, further comprising:
pre-heating, by the light source, the first conductive bump to a predetermined temperature.

15. The method of claim 13, further comprising:
post-heating, by the light source, the first conductive bump and the second conductive bump to integrate them together.

16. A semiconductor device, wherein the semiconductor device is made using the method of claim 1.
